(19) United States
(12) Patent Application Publication
(10) Pub. No.: US 2025/0329551 A1
(43) Pub. Date: Oct. 23, 2025

(54) Metal Feature Bonding And Substrate Release Process

(71) Applicant: RAYTHEON COMPANY, Waltham, MA (US)

(72) Inventors: Aaron GEORGE, San Diego, CA (US); Haley Steffen, Cedar Rapids, IA (US)

(73) Assignee: RAYTHEON COMPANY, Waltham, MA (US)

(21) Appl. No.: 18/641,013

(22) Filed: Apr. 19, 2024

(51) Int. Cl. H01L 21/603; B23K 20/02; B23K 101/36

(52) U.S. Cl. CPC H01L 21/603; B23K 20/023; B23K 2101/36

(57) ABSTRACT

Methods for preparing metal structures on substrates by providing at least two substrates on which different parts of the metal structure are formed, which are bonded together to form the metal structure by thermocompression bonding, thermosonic bonding or transient liquid phase bonding such that a hermetic seal is provided and an optional hermetically sealed cavity forms in the structure, and releasing at least one of the substrates from the thereto bonded metal structure by removing a seed layer or sacrificial layer by an etching or reverse plating technique.

### FIELD

The subject matter disclosed relates to the bonding of metal features on a substrate to form three dimensional metal structures and to their release from the substrate.

### BACKGROUND

The fabrication of high-resolution complex metal structures requires the use of a substrate material. To enable free-standing complex metal structures, a process is needed not only to build the structures, but to also precisely and completely remove the metal structures from one or more of the substrate materials used without damage to the structures.

As such, bonding and release methods are needed for fabrication of complex free-standing thin metal structures, which are often delicate and fragile.

### SUMMARY

In an embodiment, a method of preparing a metal structure on a substrate comprising providing at least two substrates,
where at least a first of said two substrates is provided with a seed layer and/or a sacrificial layer and thereon a metal feature layer,
where a second of said at least two substrates is provided with a metal structure, which contains an optional void that is open at least on one of its sides,
positioning the at least two substrates such that the metal feature layer faces the metal structure containing the optional void,
bonding the metal feature layer with the metal structure containing the optional void by thermocompression bonding, thermosonic bonding or transient liquid phase bonding such that a seal is provided and the optional void forms an optional hermetically sealed cavity, releasing the first of said two substrates from the thereto bonded metal structure by removing the seed layer and/or the sacrificial layer by an etching or reverse plating technique.

In a further embodiment, a method of preparing a metal structure on a substrate comprising
providing at least two substrates,
   where each of the at least a first and second of said two substrates is provided with a seed layer and/or a sacrificial layer,
   where at least a first of said two substrates is provided with a metal feature layer either directly or indirectly on the seed layer and/or a sacrificial layer,
   where a second of said at least two substrates is provided with a metal structure either directly or indirectly on the seed layer and/or a sacrificial layer, which contains an optional void that is open at least on one of its sides,
positioning the at least two substrates such that the metal feature layer faces the metal structure containing the optional void,
bonding the metal feature layer with the metal structure containing the optional void by thermocompression bonding, thermosonic bonding or transient liquid phase bonding such that a seal is provided and the void forms an optional hermetically sealed cavity,
releasing the first and/or second of said two substrates from the thereto bonded metal structure by removing the seed layer and/or the sacrificial layer by an etching or reverse plating technique.

And in another embodiment, a method of preparing a metal structure on a substrate comprising
providing at least two substrates,
   where one or both of a first and a second of said at least two substrates is provided with a seed layer and/or a sacrificial layer,
   where the first of said two substrates is provided with a first part of a metal structure either directly or indirectly on the seed layer and/or a sacrificial layer, if present, or directly on the substrate,
   where the second of said two substrates is provided with a second part of a metal structure either directly or indirectly on the seed layer and/or a sacrificial layer, if present, or directly on the substrate,
      where the first and second part metal structures on the first and second substrates are complementary such that when they are positioned to face each other, they form a complete structure, which structure has an optional cavity that is closed from all sides,
positioning the at least two substrates such that the structure is formed,
bonding the first and second part metal structures together by thermocompression bonding, thermosonic bonding or transient liquid phase bonding such that a seal is provided and an optional hermetically sealed cavity is formed,
releasing the first and/or second of said at least two substrates from the thereto bonded metal structure by removing the seed layer and/or the sacrificial layer by an etching or reverse plating technique.

In any of the embodiments disclosed herein, wherein the structure can be a thermal ground plane, oscillating heat pipe, microfluidic connector, hermetically sealed cavity, probe card, filter, a sensor, a microchip, integrated circuitry, rocket nozzle component, a radio frequency RF component, a chemical microfluidics component, or a decorative or security application.

In any of the embodiments disclosed herein, wherein the structure can contain a hermetically sealed cavity.

In any of the embodiments disclosed herein, wherein the bonding can be achieved by thermocompression bonding, which is optionally performed by a die.

In any of the embodiments disclosed herein, wherein the bonding can be between gold to gold, gold to copper, gold to aluminum, gold to silver, silver to aluminum, silver to copper, copper to copper, copper to aluminum or aluminum to aluminum.

In any of the embodiments disclosed herein, wherein one or more rigid support features can be provided on the surface of the second substrate by one or more sides of the metal structure, thereby preventing crushing or damage or deforming of the structure during the bonding step.

In any of the embodiments disclosed herein, wherein the metal structures can be released from all substrates and forms a free-standing metal structure.

### BRIEF DESCRIPTION OF DRAWINGS

Implementations of the inventive concepts disclosed herein may be better understood when consideration is given to the following detailed description thereof. Such descriptions make reference to the included drawings, which are not necessarily to scale, and which some features may be exaggerated and some features may be omitted or may be represented schematically in the interest of clarity. Like reference numerals in the drawings may represent and refer to the same or similar element, feature, or function.

FIG. 1 illustrates items manufactured on a substrate, which are released from the substrate and fixed onto another substrate;

FIG. 2 illustrates steps of a manufacturing process of an assembly having a hermetically sealed cavity;

FIG. 3 illustrates a step of an alternate approach in a manufacturing process similar to the overall process shown in FIG. 2 of an assembly having a hermetically sealed cavity;

FIG. 4 illustrates a manufactured integrated circuit part having been fabricated by metal structure fabrication as disclosed herein being integrated into a larger electronics assembly.

### LEGEND FOR FIGURES

1 substrate
2 seed layer
3a metal feature, such as Cu, Au, Al or Ag
3b sacrificial material
4 metal feature such as Au, Al, Ag or Cu
5 partially prepared cavity assembly
6 hermetically sealed cavity
7 sacrificial layer
8 seed layer
9 completed hermetically sealed cavity assembly
21 integrated circuit with metal feature bonded flip-chip assembly
22 integrated circuit with metal feature bonded flip-chip assembly wire bond assembly

### DETAILED DESCRIPTION

Disclosed are bonding and release methods for the fabrication of complex free-standing or substrate bound thin metal structures such as thermal ground planes, oscillating heat pipes, microfluidic connectors, hermetically sealed cavities, probe cards, filters, and sensors (sound, vibration, temperature, pressure, etc.), and microchips, including silicon microchips, integrated circuitry, rocket nozzles, therein particularly thermal management, advanced low-loss RF components (filters, manifolds, radiators, etc.), and chemical microfluidics (DNA sequencing, droplet chemistry, etc.) or in decorative or security applications.

Some of the structures to be prepared require hermetic sealing, e.g., of a compartment or cavity in the structure, which is achieved by a bonding method, such as thermocompression bonding, thermosonic, or transient liquid phase bonding. Metal features may be composed of the same or different materials, the same or different shapes and have the same or different thicknesses to form three dimensional structures.

Thermocompression bonding concerns a wafer bonding technique where two metals pieces, which may be made of the same metal or different, e.g. gold-gold (Au), are brought into atomic contact applying force and heat simultaneously. At the contact surfaces or points, diffusion of the metals occurs, such that atoms migrate from one crystal lattice of one of the metal pieces to the crystal lattice of the other. As a result of this atomic interaction the surfaces are bonded or welded together. As a result of this, some call this technique also by names such as thermocompression welding or solid-state welding, among other options such as diffusion bonding or pressure joining. Noteworthy is that there is no glue or adhesive or other material added between the metals to be bonded. Indeed the presence of additional materials between the metal pieces to be joined is generally not desired. In this regard, care is usually taken to have clean surfaces of the metals at least on their surfaces that are to be joined/bonded together. Typical metals that may be bonded by thermocompression include copper (Cu), gold (Au), silver (Ag) and aluminum (Al), among others.

Thermocompression bonding success is a relationship between temperature, force, and time. A successful bonding window will depend on the material being bonded and its diffusion characteristics. Higher melting temperature metals will typically require a higher temperature to bond. Depending on other limitations of the items being bonded (for example, limitations in temperature or applied force due to other functions on a die), these parameters of temperature, force, and time may be adjusted within a wide window, in some cases hundreds of degrees and hundreds of Newtons of force, with time dwelling at temperature of seconds, minutes, or even hours.

Of equal importance to the bond are the presence of any oxide or other debris or residue on the bond surface, the surface area being bonded, the flatness of the bond surface, and the flatness and uniformity of the equipment used to apply the force and pressure. Bonding can be performed in air, inert gas, vacuum, or reducing gas environments depending on the materials being bonded. Care must be taken to avoid excessive growth of oxide at the bond temperature for oxide forming materials.

Thermosonic bonding relies on forming a bond by the use of ultrasonic, thermal and mechanical (force) energies by the simultaneously delivery of a force and vibratory or scrubbing motion to interfacial contact points between a pre-heated deforming lead-wire and a metallized surface. As a result of frictional action and ultrasonic softening induced in the preheated lead wire during the bonding cycle, thermosonic bonding can be used to reliably bond high melting point lead wires (such as gold, aluminum and copper) using relatively low bonding parameters, e.g., low pressures and low heat comparatively to other bonding techniques. This allows the use of this technique on sensitive materials, such as fragile silicon circuit chips where both the pressure and heat should be minimized to avoid damage to the materials to be joined, e.g., circuit chips and components thereof to be bonded to the chips.

Noted is that much of the same complexities of thermocompression bonding, as discussed above, apply here as well in the case of thermosonic bonding,

Transient liquid phase bonding involves the diffusion of an element or alloy with a lower melting point in an interlayer into the lattice and grain boundaries of surfaces to be bonded. Thus, a thin layer of liquid spreads along the interface to form a joint at a lower temperature than the melting point of either of the bonded materials. Noted is that this process relies on the isothermal solidification of the filler metal. While holding the temperature above the filler metal's melting point, interdiffusion shifts the composition away from eutectic, so solidification occurs at the process temperature. If sufficient interdiffusion occurs, the joint will remain solid and strong well above the original melt process temperature. As such, the liquid solidifies before cooling. Consideration is given in this technique to the characteristics of the metal chosen for the interlayer, such as its wettability, flow characteristics, high stability to prevent reactions with the base materials, and the ability to form a composition having a re-melt temperature higher than the bonding temperature. This technique can be used to join many metallic and/or ceramic surfaces, e.g., metal to metal, e.g., gold to copper, silver to aluminum, copper to aluminum, gold to aluminum, or metal to ceramics or ceramics to ceramics.

Transient liquid phase bonding is useful in cases where a thermocompression or thermosonic bond is impractical due to temperature limitations. And due to the brief time with a liquid state, can overcome some surface roughness that can be an issue in thermocompression bonding.

Once materials forming structures are bonded and built on a surface, their successful full removal without damage to the formed structure is a next optional step. Thus, the prepared patterned metal features are released from one or more of their fabrication substrates to form high-resolution thin metal features that are either completely free standing or one that is attached to one single substrate. Resultant metal features that are free standing may be then attached to a substrate other than the one they were fabricated on or may be free-standing.

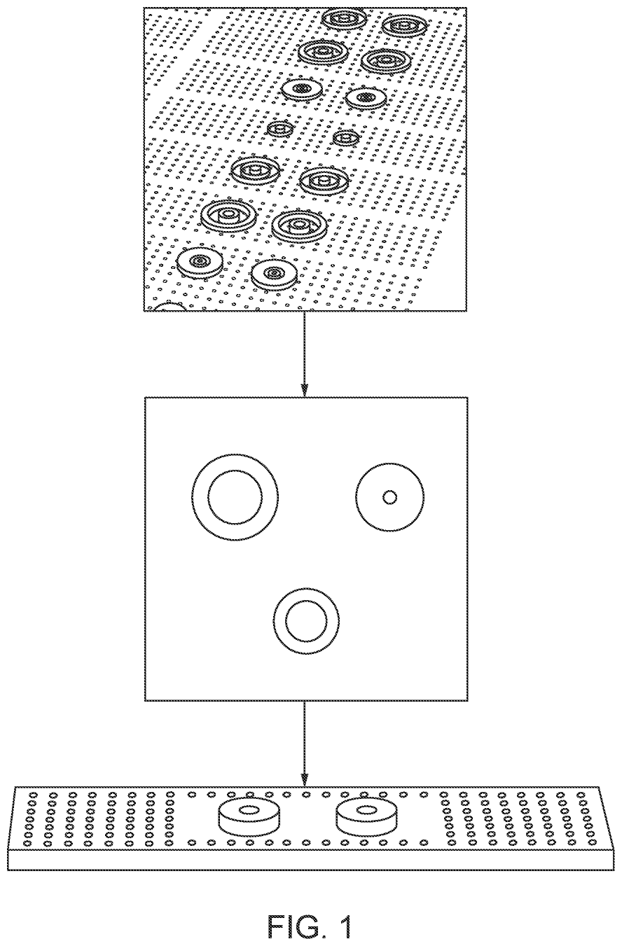

One embodiment, which is illustrated in FIG. 1, concerns the preparation of Cu microscale features of various sizes and shapes, which are prepared or grown on a substrate, from which the Cu microscale features are released, and then optionally the released Cu microscale features are bonded to another chip by, e.g., Cu-Cu thermocompression.

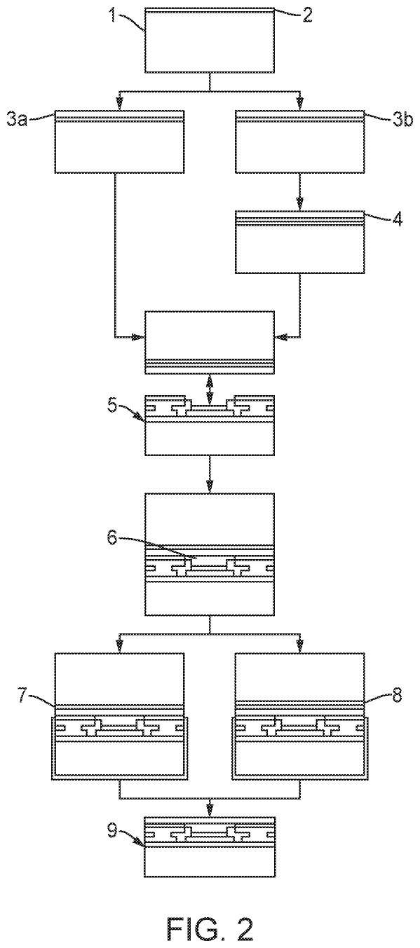

FIG. 2 illustrates an exemplary process, which in this example works through various process steps and potential variations thereof in the preparation of an assembly that requires a hermetically sealed cavity.

A substrate (1) is chosen, which in this embodiment can be Al₂O₃, but it can be other substrates as well, for example, BeO, diamond, Fe₂O₃, GaAs, Si, SiC, SiO₂, Si₃N₄, AlN, organic substrates. On a surface of the substrate a seed layer (2), which is typically a metal, for example, titanium, tungsten, copper, palladium or gold, is deposited or otherwise formed.

A purpose of the seed layer is for electroplating metal to form metal features. A seed layer is optional and not required for all embodiments, i.e., certain embodiments however benefit from the presence of a seed layer.

In a next step, a metal feature (3a), such as Cu, Au, Al or Ag may be provided directly onto the seed layer, or alternatively, a sacrificial material (3b) may be provided onto the seed layer, which may be also be Cu, or another metal such as Au, Al or Ag, various oxides, for example, SiO₂, or process compatible organic materials. In case a sacrificial layer is provided, on top of said sacrificial layer, a metal feature (4) such as Au, Al, Ag or Cu can be provided.

In case an organic material is used as the sacrificial material, it has to be able to withstand conditions used during the processing parameters, including temperatures of up to 350° C.

Depending on the metal feature being applied, the sacrificial material may also need to withstand or be protectable against a variety of electroplating chemistries and wet or plasma based etchants.

In a next step, a partially already prepared cavity assembly (5), i.e., one without having thereon a metal feature, is provided, onto which, for example, the substrate with the sacrificial layer on top of which is the metal feature, is placed with the metal feature facing the partially already prepared cavity assembly (as show in the figure). The two are compressed under conditions to achieve a thermocompression bond, for example, an Au—Au bond, Cu—Cu bond or Au—Cu bond, or Al—Al, Ag—Ag, Ag—Au or Au—Al bond.

Other options also exist for achieving the bond, such as, thermosonic or transient liquid phase or even other bonding methods are possible, which include solder, AuSn eutectic, etc.,

Noted is that variation of fill gasses or vacuum are also possible, which in this embodiment contains a void that once sealed by the metal feature achieves a hermetically sealed cavity (6).

In a following step, either a sacrificial layer (7) or a seed layer (8) is removed, e.g., by an etching process, including wet etching, or reverse plating technique to expose or release the three-dimensional structure that was intended to be formed. To achieve the successful removal of sufficient amount of the sacrificial and/or seed layer, it is important that the etching or reverse plating solution has access to the sacrificial and/or seed layer. While typically the structure will block access to said layer(s) where the structure is mounted thereon, at least on some of the sides of the structure or on some sides of the substrate's edges exposure of the sacrificial and/or seed layer is needed so that the etching or reverse plating solution or bombardment ions can remove said layer.

Wet etching usually uses an etchant compound or composition, such as various acids, e.g., strong acids, such as, H₂SO₄, HCl, FeCl₃, or other etching chemicals, such as H₂O₂, or commercial etchant mixtures specific to the material being removed to cut into and thereby remove the sacrificial layer. In this type of removal process one can cover areas or parts that are to be protected from the etchant with material that is resistant to the etchant, and leave exposed only areas or layers that are to be etched away, for example, the sacrificial layer or parts of the sacrificial layer, e.g., which are sufficient to release the structure built from the substrate. Further options include heated etch chemistries, and agitation of the etch chemistry or the device may be needed to successfully etch the sacrificial layer.

When reverse plating is used for the removal of the sacrificial layer, which is typically a metal as described above, the process involves the use of a highly ionic solution and an electrical current to remove the sacrificial layer.

A reverse plating removal process, also called stripping, will typically involve an electroplating chemistry similar to one used to plate the material onto the substrate, with an ionic carrier solution. However current is reversed from typical electroplating, and the sacrificial material on the substrate becomes the anode.

The removed material can be termed a sacrificial material collectively irrespective of whether it was a seed layer or a sacrificial layer (as it is in the end sacrificed by, e.g., etching away), while the material that forms part of the desired structure, in this case a completed cavity assembly (9) having thereon a metal membrane material that hermetically seals a cavity, is the desired structure. This assembly may then be sent for further processing or incorporation into another larger assembly.

Noted is that an option is also to release the desired structures from all substrates, so that it may be a freestanding structure, including the substrate that contained thereon the structure. Such free standing structure may then be used as is or may be mounted on a different substrate.

In this type of situation, a sacrificial and/or seed layer is additionally present on the substrate with the structure thereon, wherein the sacrificial and/or seed layer is present between the substrate and the structure. The release of the structure then can be achieved with any of the methods disclosed herein to lead to the free standing structure. The release of the two substrates can be achieved simultaneously or separate with the same or different methods.

In many situations two assemblies partially build on different substrates are bonded together by, e.g., the use of thermocompression where the substrates are placed into a die, or by other suitable methods, such as soldering or thermosonic or transient liquid bonding, with the respective structures facing each other, and then compressed to form a hermetic seal or weld on their respective surfaces that are in contact with each other.

Noted is that the processes disclosed herein allow for the stepwise preparation of highly complicated intricate structures using one to many steps, including 2, 3, 4, 5, 10, and so on steps, where various layers of materials are bonded by, e.g., thermocompression, to the structure, followed by the removal of at least one of the substrates then to be followed up with a further likewise step where an additional layer or several layers are added by, e.g., thermocompression, to the already built structure, thereby building structures in a stepwise manner with intricate complicated details or voids, cavities, channels, etc., that would not be or even could not be achieved by other preparation methods, especially when considering the nature of the structures build being made of thin materials.

Typical sizes of the structures can vary significantly, for example, in the case of a seal ring, the minimum width may be 80 to 150 microns, wherein a hermetic seals may be achieved. Metal feature thicknesses of structures being built can be as low as 1 micron, 10 microns, 20 microns, 30 microns, 40 microns, 50 microns, with no limitation on the upper limit for metal feature thickness, but ranges for embodiments include 1 to 10 and 20 to 450 microns.

In one embodiment, the bonding and release process described within this disclosure is performed with metal features on a substrate which is subsequently removed. The substrate provides support for the metal features; therefore the patterning of physical support structures is not needed with this method, although it may be included.

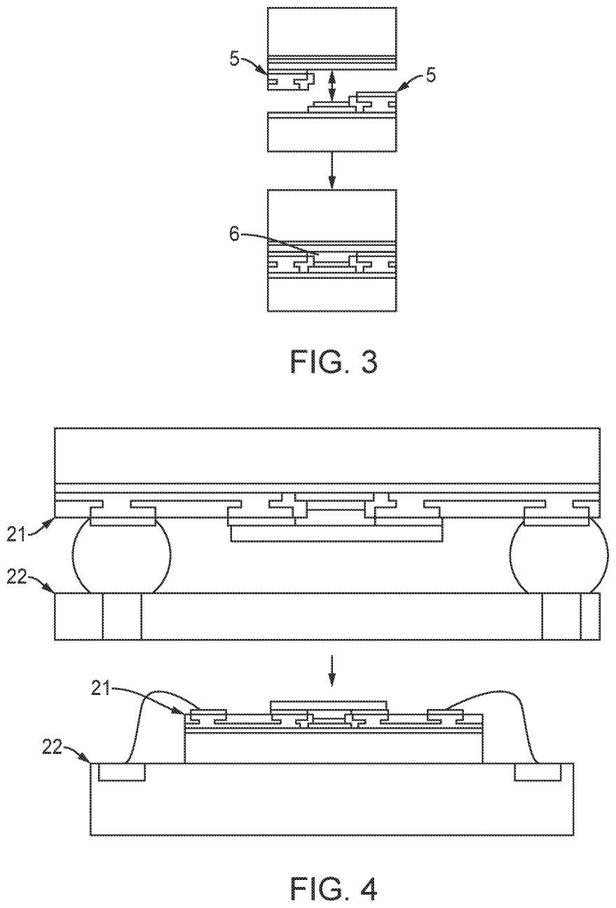

In an alternate configuration, as is it apparent that the various disclosed bonding methods can not only seal together a completely flat layer with an already partially formed structure, two different complimentary structures may be formed on two different substrates, which when facing each other and bonded by any of the methods disclosed herein, form a complete structure that can contain a hermetically sealed cavity. For example, each of the structures on the two substrates may contain two or more sides of the cavity to be formed, and when bonded together, form said cavity. Such a process step is illustrated in FIG. 3.

In one aspect, the substrate release process is made compatible with the use of an integrated circuit die and/or with the use of microelectronics packaging layers. When the structures being built concern integrated circuits, typical process of preparation temperatures should be kept at or below 400° C., for example, between 220 to 350° C. so as to avoid damage to the integrated circuits being built, in the case of CMOS integration, or to the substrate used in case it is a wafer, such as a silicon wafer, which can be a semiconducting substrate material, e.g., crystalline silicon material, more generally. This way, the performance of the built integrated circuitry is not affected by the processing temperatures used. See, e.g., Sedky et al., Experimental determination of the maximum post-process annealing temperature for standard CMOS wafers, IEEE Transactions on Electron Devices, vol. 48, issue 2, pp. 377-385, 2001. It is worth noting that the integration process described herein is compatible for high temperature subsequent processes or operational temperatures and should not be assumed to be limited to lower temperatures.

Following metal structure fabrication on an integrated circuit part, the integrated circuit may be integrated into a larger electronics assembly by methods familiar to those skilled in the art including, but not limited to, wire bond or flip-chip integration to another component. Other components may include another integrated circuit, such as an application specific integrated circuit (ASIC), an interposer, an organic interposer, or a printed circuit board. FIG. 4 shows such a general process.

In sum, the process techniques disclosed herein can be used for the building of structures for a huge number of applications. For example, the bonding and release methods are applicable for fabrication of complex free-standing thin metal structures such as thermal ground planes, oscillating heat pipes, microfluidic connectors, probe cards, filters, and so on, as already indicated above, for a large variety of industries, including the integrated circuitry industry, laboratory work, such as DNA sequencing, and even for the preparation of structures usable in decorative or security applications, e.g., an RF component, or a visually otherwise hard to impossible to reproduce structure preparation.

As will be appreciated by one skilled in the art, the embodiments described herein may be embodied as a method of use or preparation, a product, including a part for use in various assemblies, or use per se.

The description of the embodiments described herein has been presented for purposes of illustration and description, but is not intended to be exhaustive or limited to the invention in the form disclosed. Many modifications and variations will be apparent to those of ordinary skill without departing from the scope and spirit of the invention. The embodiments were chosen and described in order to best explain the principles of the invention and the practical application, and to enable others of ordinary skill in the art to understand the invention for embodiments with various modifications as are suited to the particular use contemplated.

Modifications and equivalents may be made to the features disclosed without departing from the spirit or scope of the invention. Thus, it is intended that the embodiments described herein covers the modifications and variations disclosed above, including changes that lead to equivalents, i.e., modifications and equivalents may be made to the features of the claims without departing from the scope of the invention.

1. A method of preparing a metal structure on a substrate comprising
providing at least two substrates,
where at least a first of said two substrates is provided with a seed layer and/or a sacrificial layer and thereon a metal feature layer,
where a second of said at least two substrates is provided with a metal structure, which contains an optional void that is open at least on one of its sides,
positioning the at least two substrates such that the metal feature layer faces the metal structure containing the optional void,
bonding the metal feature layer with the metal structure containing the optional void by thermocompression bonding, thermosonic bonding or transient liquid phase bonding such that a seal is provided and the optional void forms an optional hermetically sealed cavity,
releasing the first of said two substrates from the thereto bonded metal structure by removing the seed layer and/or the sacrificial layer by an etching or reverse plating technique.

2. The method according to claim 1, wherein the structure is a thermal ground plane, oscillating heat pipe, microfluidic connector, hermetically sealed cavity, probe card, filter, a sensor, a microchip, integrated circuitry, rocket nozzle component, a radio frequency RF component, a chemical microfluidics component, or a decorative or security application.

3. The method according to claim 1, wherein the structure contains a hermetically sealed cavity.

4. The method according to claim 1, wherein the bonding is achieved by thermocompression bonding, which is optionally performed on an electronic component.

5. The method according to claim 1, wherein the bonding is between gold to gold, gold to copper, gold to aluminum, gold to silver, silver to aluminum, silver to copper, copper to copper, copper to aluminum or aluminum to aluminum.

6. The method according to claim 1, wherein one or more rigid support features are provided on the surface of the second substrate by one or more sides of the metal structure, thereby preventing crushing or damage or deforming of the structure during the bonding step.

7. The method according to claim 1, wherein the metal structure is released from all substrates and forms a free-standing metal structure.

8. A method of preparing a metal structure on a substrate comprising
providing at least two substrates,
where each of the at least a first and second of said two substrates is provided with a seed layer and/or a sacrificial layer,
where at least a first of said two substrates is provided with a metal feature layer either directly or indirectly on the seed layer and/or a sacrificial layer,
where a second of said at least two substrates is provided with a metal structure either directly or indirectly on the seed layer and/or a sacrificial layer, which contains an optional void that is open at least on one of its sides,
positioning the at least two substrates such that the metal feature layer faces the metal structure containing the optional void,
bonding the metal feature layer with the metal structure containing the optional void by thermocompression bonding, thermosonic bonding or transient liquid phase bonding such that a seal is provided and the void forms an optional hermetically sealed cavity,
releasing the first and/or second of said two substrates from the thereto bonded metal structure by removing the seed layer and/or the sacrificial layer by an etching or reverse plating technique.

9. The method according to claim 8, wherein the structure is a thermal ground plane, oscillating heat pipe, microfluidic connector, hermetically sealed cavity, probe card, filter, a sensor, a microchip, integrated circuitry, rocket nozzle component, a radio frequency RF component, a chemical microfluidics component, or a decorative or security application.

10. The method according to claim 8, wherein the structure contains a hermetically sealed cavity.

11. The method according to claim 8, wherein the bonding is achieved by thermocompression bonding, which is optionally performed on an electronic component.

12. The method according to claim 8, wherein the bonding is between gold to gold, gold to copper, gold to aluminum, gold to silver, silver to aluminum, silver to copper, copper to copper, copper to aluminum or aluminum to aluminum.

13. The method according to claim 8, wherein one or more rigid support features are provided on the surface of the second substrate by one or more sides of the metal structure, thereby preventing crushing or damage or deforming of the structure during the bonding step.

14. The method according to claim 8, wherein the metal structures is released from all substrates and forms a free-standing metal structure.

15. A method of preparing a metal structure on a substrate comprising
providing at least two substrates,
where one or both of a first and a second of said at least two substrates is provided with a seed layer and/or a sacrificial layer,
where the first of said two substrates is provided with a first part of a metal structure either directly or indirectly on the seed layer and/or a sacrificial layer, if present, or directly on the substrate,
where the second of said two substrates is provided with a second part of a metal structure either directly or indirectly on the seed layer and/or a sacrificial layer, if present, or directly on the substrate,
where the first and second part metal structures on the first and second substrates are complementary such that when they are positioned to face each other, they form a complete structure, which structure has an optional cavity that is closed from all sides,
positioning the at least two substrates such that the structure is formed,
bonding the first and second part metal structures together by thermocompression bonding, thermosonic bonding or transient liquid phase bonding such that a seal is provided and an optional hermetically sealed cavity is formed,
releasing the first and/or second of said at least two substrates from the thereto bonded metal structure by removing the seed layer and/or the sacrificial layer by an etching or reverse plating technique.

16. The method according to claim 15, wherein the structure is a thermal ground plane, oscillating heat pipe, microfluidic connector, hermetically sealed cavity, probe card, filter, a sensor, a microchip, integrated circuitry, rocket nozzle component, a radio frequency RF component, a chemical microfluidics component, or a decorative or security application.

17. The method according to claim 15, wherein the structure contains a hermetically sealed cavity.

18. The method according to claim 15, wherein the bonding is achieved by thermocompression bonding, which is optionally performed on an electronic component.

19. The method according to claim 15, wherein the bonding is between gold to gold, gold to copper, gold to aluminum, gold to silver, silver to aluminum, silver to copper, copper to copper, copper to aluminum or aluminum to aluminum.

20. The method according to claim 15, wherein one or more rigid support features are provided on the surface of the second substrate by one or more sides of the metal structure, thereby preventing crushing or damage or deforming of the structure during the bonding step.
